(19) United States
(12) Patent Application Publication
(10) Pub. No.: US 2025/0258787 A1
(43) Pub. Date: Aug. 14, 2025

(54) HANDSHAKE SIGNAL SPLITTING CIRCUIT, METHOD, APPARATUS AND DEVICE, AND NON-VOLATILE READABLE STORAGE MEDIUM

(71) Applicant: IEIT SYSTEMS CO., LTD., Jinan, Shandong (CN)

(72) Inventors: Hongliang WANG, Jinan, Shandong (CN); Qi MOU, Jinan, Shandong (CN); Shengcai LU, Jinan, Shandong (CN); Wei LIU, Jinan, Shandong (CN); Deshan ZHANG, Jinan, Shandong (CN)

(73) Assignee: IEIT SYSTEMS CO., LTD., Jinan, Shandong (CN)

(21) Appl. No.: 18/879,709

(22) PCT Filed: Sep. 25, 2023
(86) PCT No.: PCT/CN2023/121189

§ 371 Date: Dec. 27, 2024

(30) Foreign Application Priority Data
Feb. 7, 2023 (CN) 202310070901.7

(51) Int. Cl. G06F 13/20; H03K 19/20

(52) U.S. Cl. CPC G06F 13/20; H03K 19/20; G06F 2213/40

(57) ABSTRACT

Disclosed are a circuit, method, apparatus and device of splitting a handshake signal, and a non-volatile readable storage medium. Logic control circuits can only control, when a valid signal output end of a front-end module outputs a first level and feedback signal output ends output a second level, the back-end modules corresponding to the logic control circuits to complete a current handshake, and output, before the front-end module completes the current handshake, a level opposite to the first level to valid signal receiving ends of the back-end modules corresponding to the logic control circuits, and the second level to a first level processing module, such that the first level processing module outputs the second level after all the back-end modules complete the current handshake, and thus the front-end module completes the current handshake.

### CROSS-REFERENCE TO RELATED APPLICATION

The present application is a National Stage Application of PCT International Application No.: PCT/CN2023/121189 filed on Sep. 25, 2023, which claims priority to Chinese Patent Application 202310070901.7, filed in the China National Intellectual Property Administration on Feb. 7, 2023, the disclosure of which is incorporated herein by reference in its entirety.

### TECHNICAL FIELD

The disclosure relates to the field of digital circuits, and in particular to a circuit of splitting a handshake signal, and the disclosure further relates to a method, apparatus and device of splitting a handshake signal, a non-volatile readable storage medium, a digital chip and a server.

### BACKGROUND

It is often necessary to use a handshake signal in order to ensure effective transmission of data and prevent data loss between designs or modules in a design of a digital circuit such as a digital integrated circuit (IC)/field-programmable gate array (FPGA). The handshake signal comprises a valid signal sent by a front-end module (which sends data) and a feedback signal sent by a back-end module (which receives data). When the valid signal is at a first level and the feedback signal is at a second level, the signal will be transmitted from the front-end module to the back-end module, so as to complete a handshake. With reference to FIG. 2, a schematic application diagram of a valid/stop handshake protocol is shown. The handshake protocol is based on a principle that data will be transmitted when valid (valid signal) is high (at the first level) and stop (feedback signal) is low (at the second level). The valid signal serves to indicate whether the data output by a front-end module A is valid, and the data is valid when valid is high; and the stop signal is used for a back-end module B to inform the front-end module A of whether to receive the data, and it is indicated that the back-end module B does not receive the data from the module A when stop is high.

In practical application, a front-end module may correspond to a plurality of back-end modules, that is, the plurality of back-end modules need to receive the same data from the same front-end module, it is necessary to configure a circuit of splitting a handshake signal between the front-end module and the plurality of back-end modules. However, the plurality of back-end modules can only simultaneously receive data from the front-end module in the circuit of splitting a handshake signal in the related art, which reduces flexibility of data calculation by the back-end modules and limits application scenarios.

So, the above problem in the related art has not yet been solved at present.

### SUMMARY

An objective of the disclosure is to provide a circuit of splitting a handshake signal, which support for multiple a plurality of back-end modules to receive date simultaneously/timed, improves flexibility of data calculation by the back-end modules, and expands application scenarios; and another objective of the disclosure is to provide a method, apparatus and device of splitting a handshake signal, a non-volatile readable storage medium, a digital chip and a server, which support for multiple a plurality of back-end modules to receive date simultaneously/timed, improve flexibility of data calculation by the back-end modules, and expand application scenarios.

In order to solve the above technical problem, in a first aspect, the disclosure provides a circuit of splitting a handshake signal. The circuit of splitting a handshake signal comprises:
a first level processing module, wherein an output end of the first level processing module is connected to a feedback signal receiving end of a front-end module, and each of input ends of the first level processing module is connected one-to-one with a first output end of each of logic control circuits, the first level processing module is configured to output a second level only when each of the input ends is at the second level;
a second level processing module, wherein a first input end of the second level processing module is connected to the output end of the first level processing module, and a second input end of the second level processing module is connected to a valid signal output end of the front-end module; and
the logic control circuits, wherein a first input end of each of the logic control circuits is connected to an output end of the second level processing module, a second input end of the each of the logic control circuits is connected to a feedback signal output end of a back-end module uniquely corresponding to the each of the logic control circuits, a second output end of the each of the logic control circuits is connected to a valid signal receiving end of the back-end module uniquely corresponding to the each of the logic control circuits, and a third input end of the each of the logic control circuits is connected to the valid signal output end of the front-end module, the each of the logic control circuits is configured to, in cooperation with an output signal of the second level processing module, send, when the valid signal output end outputs a first level and the feedback signal output end connected to the each of the logic control circuits outputs the second level, the first level to the valid signal receiving end connected to the each of the logic control circuits, to cause the each of the logic control circuits and the back-end module corresponding to the each of the logic control circuits to complete a current handshake; and output, after the back-end module corresponding to the each of the logic control circuits completes the current handshake and before the front-end module completes the current handshake, a level opposite to the first level to the valid signal receiving end connected to the each of the logic control circuits and the second level to the first level processing module.

Optionally, the front-end module is configured to prepare a piece of data during each handshake, the back-end module is configured to acquire the data corresponding to the current handshake while the current handshake is successful, and the front-end module is further configured to prepare a next piece of data after the back-end module acquires the data corresponding to the current handshake.

Optionally, the each of the logic control circuits comprises a logic control sub-circuit, a first logic processing sub-module and a second logic processing sub-module, wherein
a first input end of the logic control sub-circuit is connected to the output end of the second level processing module, an output end of the logic control sub-circuit is connected to a first input end of the first logic processing sub-module and a first input end of the second logic processing sub-module respectively, a second input end of the first logic processing sub-module is connected to the valid signal output end of the front-end module, an output end of the first logic processing sub-module is used as the second output end of the each of the logic control circuits, a second input end of the second logic processing sub-module is used as the second input end of the each of the logic control circuits, and an output end of the second logic processing sub-module is used as a first output end of the each of the logic control circuits and is connected to a second input end of the logic control sub-circuit;
the logic control sub-circuit is configured to, in cooperation with the output signal of the second level processing module, output the first level when the valid signal output end outputs the first level and the feedback signal output end corresponding to the each of the logic control circuits outputs the second level, to cause the each of the logic control circuits and the back-end module corresponding to the each of the logic control circuits to complete the current handshake; and output the second level after the back-end module corresponding to the each of the logic control circuits completes the current handshake and before the front-end module completes the current handshake;
the first logic processing sub-module is configured to output the first level only when the first input end and the second input end of the first logic processing sub-module are both at the first level;
the second logic processing sub-module is configured to output the second level only when the first input end and the second input end of the second logic processing sub-module are both at the second level.

Optionally, the first level is a high level, and the second level is a low level; in embodiments of present disclosure, the high level can represent 1 (“1” can be a logic “1”, which indicates 3.3V, or 5V, or an other voltage value preset in the circuit), the low level can represent 0 (“0” can be a logic “0”, which indicates 0V or an other voltage value preset in the circuit);
the first level processing module is a first OR gate; and
the first logic processing sub-module is a first AND gate, the second logic processing sub-module is a second AND gate, and the second level processing module is a third AND gate.

Optionally,
the first level processing module is configured to execute an OR operation on input signals; and
the first logic processing sub-module, the second logic processing sub-module, and the second level processing module are configured to execute an AND operation on input signals respectively.

Optionally, the logic control sub-circuit comprises a first NOT gate, a second OR gate and a register;
a first input end of the third AND gate is respectively connected to the valid signal output end of the front-end module and a second input end of the first AND gate in a logic control circuit in which the third AND gate is located, a second input end of the third AND gate is connected to the feedback signal receiving end of the front-end module, an output end of the third AND gate is connected to an input end of the first NOT gate in the logic control circuit in which the third AND gate is located, an output end of the first NOT gate is connected to a first input end of the second OR gate in the logic control circuit in which the first NOT gate is located, a second input end of the second OR gate is respectively connected to an output end of the second AND gate and one input end of the first OR gate, an output end of the second OR gate is connected to an input end of the register, and an output end of the register is used as the output end of the logic control sub-circuit; and
the register is configured to register an input signal for one clock cycle and then output the input signal.

Optionally, the first level is a high level, and the second level is the high level; in embodiments of present disclosure, the high level can represent 1 (“1” can be a logic “1”, which indicates 3.3V, or 5V, or an other voltage value preset in the circuit), the low level can represent 0(“0” can be a logic “0”, which indicates 0V or an other voltage value preset in the circuit);
the first level processing module is a first OR gate; and
the first logic processing sub-module is a first AND gate, and the second logic processing sub-module comprises a second AND gate and a second NOT gate, a first input end of the second AND gate is used as the first input end of the second logic processing sub-module, an output end of the second AND gate is used as the output end of the second logic processing sub-module, a first end of the second NOT gate is connected to a second input end of the second AND gate, and a second end of the second NOT gate is used as the second input end of the second logic processing sub-module.

Optionally,
the first level processing module is configured to execute an OR operation on input signals; and
the first logic processing sub-module is configured to execute an AND operation on input signals, and the second logic processing sub-module is configured to execute a NOT operation on a signal input at the second input end of the second logic processing sub-module, then execute an AND operation on an operation result of the NOT operation and a signal input at the first input end of the second logic processing sub-module, and output an operation result of the AND operation.

Optionally, the first level is a low level, and the second level is a high level; in embodiments of present disclosure, the high level can represent 1 (“1” can be a logic “1”, which indicates 3.3V, or 5V, or an other voltage value preset in the circuit), the low level can represent 0 (“0” can be a logic “0”, which indicates OV or an other voltage value preset in the circuit);
the first level processing module is a first OR gate; and
the first logic processing sub-module comprises a first AND gate and a third NOT gate, and the second logic processing sub-module comprises a second AND gate and a second NOT gate, a first input end of the first AND gate is used as the first input end of the first logic processing sub-module, a second input end of the first AND gate is used as the second input end of the first logic processing sub-module, an output end of the first AND gate is connected to a first end of the third NOT gate, a second end of the third NOT gate is used as the output end of the first logic processing sub-module, a first input end of the second AND gate is used as the first input end of the second logic processing sub-module, an output end of the second AND gate is used as the output end of the second logic processing sub-module, a first end of the second NOT gate is connected to a second input end of the second AND gate, and a second end of the second NOT gate is used as the second input end of the second logic processing sub-module.

Optionally,
the first level processing module is configured to execute an OR operation on input signals;
the first logic processing sub-module is configured to execute an AND operation on input signals, then execute a NOT operation on an operation result of the AND operation, and output an operation result of the NOT operation; and
the second logic processing sub-module is configured to execute a NOT operation on a signal input at the second input end of the second logic processing sub-module, then execute an AND operation on an operation result of the NOT operation and a signal input at the first input end of the second logic processing sub-module, and output an operation result of the AND operation.

Optionally, the circuit of splitting a handshake signal further comprising:
an encapsulation component configured to fix and encapsulate the first OR gate and the each of the logic control circuits.

Optionally, the circuit of splitting a handshake signal further comprising:
a signal enhancement circuit arranged at the feedback signal receiving end of the front-end module and the valid signal receiving end of each of back-end modules comprising the back-end module uniquely corresponding to the each of the logic control circuits, and configured to filter out an interference signal in a signal passing through the signal enhancement circuit.

Optionally, the signal enhancement circuit comprises:
a first filtering module arranged at the feedback signal receiving end of the front-end module, and configured to filter out an interference signal in a feedback signal passing through the first filtering module; and
second filtering modules arranged one-to-one correspondingly at valid signal receiving ends comprising the valid signal receiving end of each of the back-end modules, wherein each of the second filtering modules is configured to filter out an interference signal in a valid signal passing through the each of the second filtering modules.

Optionally, the handshake signal comprises a handshake signal of a Valid/Stop protocol.

In order to solve the above technical problem, in a second aspect, the disclosure provides a method of splitting a handshake signal. The method of splitting a handshake signal comprises:
determining a back-end module of which a feedback signal output end outputs a second level when a valid signal output end of a front-end module outputs a first level;
sending the first level to a valid signal receiving end of the determined back-end module, to cause the determined back-end module to complete a current handshake;
outputting a level opposite to the first level to the valid signal receiving end of the determined back-end module when the front-end module does not complete the current handshake; and
outputting a second level to a feedback signal receiving end of the front-end module only when all back-end modules complete the current handshake.

In order to solve the above technical problem, in a third aspect, the disclosure provides a apparatus of splitting a handshake signal. The apparatus of splitting a handshake signal comprises:
a determination module, configured to determine a back-end module of which a feedback signal output end outputs a second level when a valid signal output end of a front-end module outputs a first level;
a first sending module, configured to send the first level to a valid signal receiving end of the determined back-end module, to cause the determined back-end module to complete a current handshake;
a second sending module, configured to output a level opposite to the first level to the valid signal receiving end of the determined back-end module when the front-end module does not complete the current handshake; and
a third sending module, configured to output a second level to a feedback signal receiving end of the front-end module only when all back-end modules complete the current handshake.

In order to solve the above technical problem, in a fourth aspect, the disclosure provides a device of splitting a handshake signal. The device of splitting a handshake signal comprises:
a memory, configured to store a computer program; and
a processor, configured to implement steps of the method of splitting a handshake signal as described above when executing the computer program.

In order to solve the above technical problem, in a fifth aspect, the disclosure provides a non-volatile readable storage medium. The nonvolatile readable storage medium stores a computer program, where the computer program implements steps of the method of splitting a handshake signal as described above when executed by a processor.

In order to solve the above technical problem, in a sixth aspect, the disclosure provides a digital chip. The digital chip comprises the circuit of splitting a handshake signal as described above, a front-end module and a plurality of back-end modules, where
the circuit of splitting a handshake signal is connected to the front-end module and each of the back-end modules.

In order to solve the above technical problem, in a seventh aspect, the disclosure provides a server. The server comprises a server body, and the digital chip as described above that is connected to the server body.

The disclosure provides the circuit of splitting a handshake signal. In order to achieve time-divided reception of data by the plurality of back-end modules during signal handshake, in cooperation with the second level processing module, each of the logic control circuits corresponding to the back-end modules one to one in the disclosure can only control, when the valid signal output end of the front-end module outputs the first level and the feedback signal output end of the back-end module corresponding to the logic control circuit outputs the second level, the back-end module corresponding to the logic control circuit to complete the current handshake, and output, before the front-end module completes the current handshake, the level opposite to the first level to the valid signal receiving end of the back-end module corresponding to the logic control circuit, so as to prevent the back-end module from receiving data anew, and the second level to the first level processing module, such that the first level processing module outputs the second level after all the back-end modules complete the current handshake, and thus the front-end module completes the current handshake. Thus, simultaneous/time-divided reception of the data by the plurality of back-end modules is supported, flexibility of data calculation by the back-end modules is improved, and application scenarios are expanded.

The disclosure further provides a digital circuit including the circuit of splitting a handshake signal as described above, which has the same beneficial effects as the circuit of splitting a handshake signal as described above.

### BRIEF DESCRIPTION OF THE DRAWINGS

In order to more clearly illustrate the technical solutions in the examples of the disclosure, the accompanying drawings required for the related art and the examples will be briefly introduced below. Obviously, the accompanying drawings in the following description are merely some examples of the disclosure, and those of ordinary skill in the art would further be able to derive other accompanying drawings from these accompanying drawings without making creative efforts.

FIG. 1 is a schematic structural diagram of a circuit of splitting a handshake signal according to the disclosure;

FIG. 2 is a schematic application diagram of a valid/stop handshake protocol;

FIG. 3 is a schematic structural diagram of another circuit of splitting a handshake signal according to the disclosure;

FIG. 4 is a schematic flow diagram of a method of splitting a handshake signal according to the disclosure;

FIG. 5 is a schematic structural diagram of a apparatus of splitting a handshake signal according to the disclosure; and

FIG. 6 is a schematic structural diagram of a device of splitting a handshake signal according to the disclosure.

### DETAILED DESCRIPTION OF THE EMBODIMENTS

A core of the disclosure is to provide a circuit of splitting a handshake signal, which support for multiple a plurality of back-end modules to receive date simultaneously/timed, improves flexibility of back-end data computation, and expands application scenarios; and another core of the disclosure is to provide a splitting method, apparatus and device for a handshake signal, a non-volatile readable storage medium, a digital chip and a server, which support simultaneous/time-divided reception of data by a plurality of back-end modules, improve flexibility of back-end data computation, and expand application scenarios.

In order to make the objectives, technical solutions and advantages of the examples of the disclosure clearer, the technical solutions in the examples of the disclosure will be clearly and completely described below in combination with the accompanying drawings in the examples of the disclosure. Obviously, the described examples are some examples rather than all examples of the disclosure. On the basis of the examples in the disclosure, all other examples obtained by those of ordinary skill in the art without making creative efforts fall within the scope of protection of the disclosure.

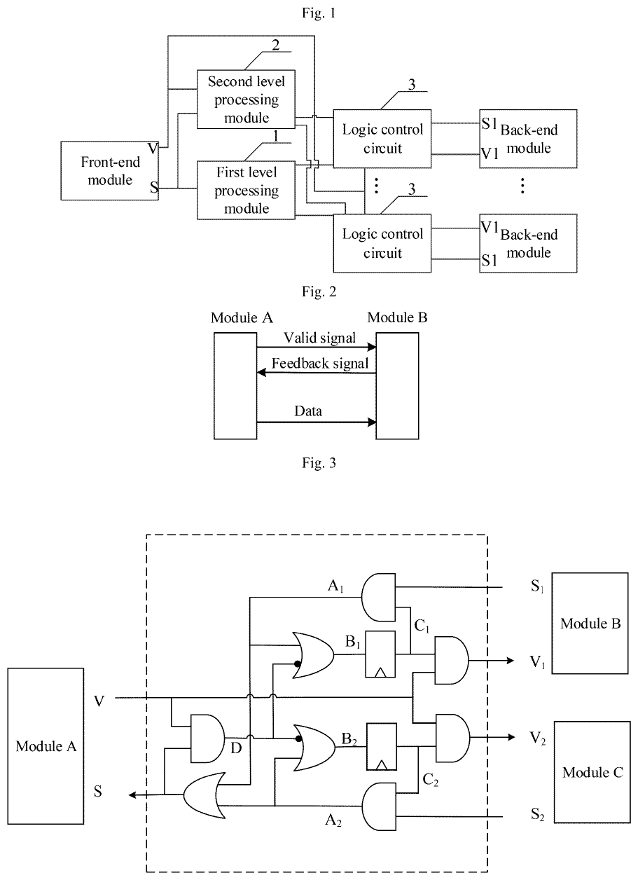

With reference to FIG. 1, a schematic structural diagram of a circuit of splitting a handshake signal according to the disclosure is shown. The circuit of splitting a handshake signal comprises:
a first level processing module, wherein an output end of the first level processing module is connected to a feedback signal receiving end of a front-end module, and each of input ends of the first level processing module is connected one-to-one with a first output end of each of logic control circuits, the first level processing module is configured to output a second level only when each of the input ends is at the second level;
a second level processing module, wherein a first input end of the second level processing module is connected to the output end of the first level processing module, and a second input end of the second level processing module is connected to a valid signal output end of the front-end module; and
the logic control circuits, wherein a first input end of each of the logic control circuits is connected to an output end of the second level processing module, a second input end of the each of the logic control circuits is connected to a feedback signal output end of a back-end module uniquely corresponding to the each of the logic control circuits, a second output end of the each of the logic control circuits is connected to a valid signal receiving end of the back-end module uniquely corresponding to the each of the logic control circuits, and a third input end of the each of the logic control circuits is connected to the valid signal output end of the front-end module, the each of the logic control circuits is configured to, in cooperation with an output signal of the second level processing module, send, when the valid signal output end outputs a first level and the feedback signal output end connected to the each of the logic control circuits outputs the second level, the first level to the valid signal receiving end connected to the each of the logic control circuits, to cause the each of the logic control circuits and the back-end module corresponding to the each of the logic control circuits to complete a current handshake; and output, after the back-end module corresponding to the each of the logic control circuits completes the current handshake and before the front-end module completes the current handshake, a level opposite to the first level to the valid signal receiving end connected to the each of the logic control circuits and the second level to the first level processing module.

Optionally, considering the technical problem as described in the background art above, and considering that for the front-end module, the back-end modules may receive data from the front-end module as long as the valid signal output end of the front-end module outputs a valid signal, and the front-end module still provides the data corresponding to the current handshake as long as the feedback signal receiving end of the front-end module does not receive a feedback signal, the circuit of splitting a handshake signal, which comprises the first level processing module, the second level processing module and the logic control circuits, is designed in the disclosure in order to achieve time-divided reception of data by the plurality of back-end modules during signal handshake. Each of the logic control circuits corresponds to the back-end module one to one, and in cooperation with the output signal of the second level processing module, may send, when the valid signal output end outputs the first level and the feedback signal output end connected to the logic control circuit outputs the second level, the first level to the valid signal receiving end connected to the logic control circuit, such that the back-end module connected to the logic control circuit completes the current handshake. In this case, although the back-end module outputs the second level from the feedback signal output end as usual, and the logic control circuit also sends the second level to the first level processing module, the first level processing module outputs the second level only when all the input ends of the first level processing module are at the second level, thereby ensuring that the front-end module may receive the second level only after all the back-end modules complete data acquisition corresponding to the current handshake. Moreover, for the back-end module that completes the current handshake, in order to ensure that the back-end module may not acquire data corresponding to the current handshake anew, the logic control circuit may output, before the front-end module completes the current handshake, the level opposite to the first level to the valid signal receiving end connected to the logic control circuit.

Whether the first level and the second level are a high level or a low level may be independently designed, which will not be limited herein by the example of the disclosure.

Optionally, the number of the back-end modules may be determined according to requirements of an actual application scenario, which will not be limited herein by the example of the disclosure.

Optionally, it is worth mentioning that the front-end module is configured to prepare a piece of data during each handshake, the back-end module is configured to acquire the data corresponding to the current handshake while the current handshake is successful, and the front-end module is further configured to prepare a next piece of data after the back-end module acquires the data corresponding to the current handshake.

The disclosure provides the circuit of splitting a handshake signal. In order to achieve time-divided reception of data by the plurality of back-end modules during signal handshake, in cooperation with the second level processing module, each of the logic control circuits corresponding to the back-end modules one to one in the disclosure can only control, when the valid signal output end of the front-end module outputs the first level and the feedback signal output end of the back-end module corresponding to the logic control circuit outputs the second level, the back-end module corresponding to the logic control circuit to complete the current handshake, and output, before the front-end module completes the current handshake, the level opposite to the first level to the valid signal receiving end of the back-end module corresponding to the logic control circuit, so as to prevent the back-end module from receiving data anew, and the second level to the first level processing module, such that the first level processing module outputs the second level after all the back-end modules complete the current handshake, and thus the front-end module completes the current handshake. Thus, simultaneous/time-divided reception of the data by the plurality of back-end modules is supported, flexibility of data calculation by the back-end modules is improved, and application scenarios are expanded.

On the basis of the above example:
as an optional example, the each of the logic control circuits comprises a logic control sub-circuit, a first logic processing sub-module and a second logic processing sub-module, wherein
a first input end of the logic control sub-circuit is connected to the output end of the second level processing module, an output end of the logic control sub-circuit is connected to a first input end of the first logic processing sub-module and a first input end of the second logic processing sub-module respectively, a second input end of the first logic processing sub-module is connected to the valid signal output end of the front-end module, an output end of the first logic processing sub-module is used as the second output end of the each of the logic control circuits, a second input end of the second logic processing sub-module is used as the second input end of the each of the logic control circuits, and an output end of the second logic processing sub-module is used as a first output end of the each of the logic control circuits and is connected to a second input end of the logic control sub-circuit;
the logic control sub-circuit is configured to, in cooperation with the output signal of the second level processing module, output the first level when the valid signal output end outputs the first level and the feedback signal output end corresponding to the each of the logic control circuits outputs the second level, to cause the each of the logic control circuits and the back-end module corresponding to the each of the logic control circuits to complete the current handshake; and output the second level after the back-end module corresponding to the each of the logic control circuits completes the current handshake and before the front-end module completes the current handshake;
the first logic processing sub-module is configured to output the first level only when the first input end and the second input end of the first logic processing sub-module are both at the first level;
the second logic processing sub-module is configured to output the second level only when the first input end and the second input end of the second logic processing sub-module are both at the second level.

Optionally, the logic control circuit in the example of the disclosure has simple structure. In cooperation with the output signal of the second level processing module, the logic control sub-circuit outputs the first level at the valid signal output end and outputs the first level when the feedback signal output end corresponding to the logic control sub-circuit outputs the second level, such that the back-end module corresponding to the logic control sub-circuit completes the current handshake; and then the logic control sub-circuit outputs the second level after the back-end module corresponding to the logic control sub-circuit completes the current handshake and before the front-end module completes the current handshake, and further simultaneously completes, by means of an output level of the logic control sub-circuit, control over a level received at the valid signal receiving end of the back-end module and a signal received at the input end of the first level processing module.

Certainly, a structure of the logic control circuit may be further of other types apart from the configuration, which will not be limited herein by the example of the disclosure.

In order to better illustrate the example of the disclosure, with reference to FIG. 3, a schematic structural diagram of another circuit of splitting a handshake signal according to the disclosure is shown. As an optional example, the first level is a high level, and the second level is a low level; in embodiments of present disclosure, the high level can represent 1 (“1” can be a logic “1”, which indicates 3.3V, or 5V, or an other voltage value preset in the circuit), the low level can represent 0 (“0” can be a logic “0”, which indicates OV or an other voltage value preset in the circuit);
the first level processing module is a first OR gate; and
the first logic processing sub-module is a first AND gate, the second logic processing sub-module is a second AND gate, and the second level processing module is a third AND gate.

Optionally, in FIG. 3, a module A is a front-end module, V is a valid signal output end of the module A, S is a feedback signal receiving end of the module A, and a module B and a module C are both back-end modules. V1 and V2 are both valid signal receiving ends, S1 and S2 are both feedback signal output ends, AND gates directly connected to the valid signal receiving ends of the back-end modules are first AND gates, and AND gates directly connected to the feedback signal output ends of the back-end modules are second AND gates. A rectangular box having triangles inside in the figure represents a register, the register and an OR gate having a NOT gate at one input end on a left side of the register jointly form a logic control sub-circuit, an AND gate of an output signal D is a second level processing module, and an OR gate having an output end directly connected to the feedback signal receiving end of the front-end module is a first level processing module.

For convenience of description, intermediate circuit signals are marked with ABCD.

Details of the circuit of splitting a handshake signal in the example of the disclosure are as follows:
(1) A1=C1&S1; and a signal A1 is at a high level when a signal C1 and a signal S1 are both at high levels, and otherwise the signal A1 is at a low level.
(2) A2=C2&S2; and a signal A2 is at the high level when a signal C2 and a signal S2 are both at the high levels, and otherwise the signal A2 is at the low level.
(3) D=S&V; and a signal D is at the high level when a signal S and a signal V are both at the high levels, and otherwise the signal D is at the low level.
(4) B1=A1|(˜D); and a signal B1 is at the low level when the signal D is at the high level and the signal A1 is at the low level, and otherwise the signal B1 is at the high level.
(5) B2=A2|(˜D); and a signal B2 is at the low level when the signal D is at the high level and the signal A2 is at the low level, and otherwise the signal B2 is at the high level.
(6) The signal C1 is an output of the signal B1 after passing through the register.
(7) The signal C2 is an output of the signal B2 after passing through the register.
(8) V1=V&C1; and a signal V1 is at the high level when the signal V and the signal C1 are both at the high level, and otherwise the signal V1 is at the low level.
(9) V2=V&C2; and a signal V2 is at the high level when the signal V and the signal C2 are both at the high level, and otherwise the signal V2 is at the low level.
(10) S=A1|A2; and a signal S is at the low level only when the signal A1 and the signal A2 are both at the low level.

Optionally, when the first level is the high level and the second level is the low level, which is a common form of handshake signals, for example, the handshake signal of a valid/stop protocol in FIG. 2 has the common form, the first level processing module may be the first OR gate, the first logic processing sub-module may be the first AND gate, the second logic processing sub-module may be the second AND gate, and the second level processing module may be the third AND gate. Thus, the circuit of splitting a handshake signal has simple structure and low implementation cost.

Certainly, each module may be further of other types apart from the optional form, which will not be limited herein by the example of the disclosure.

As an optional example, the logic control sub-circuit comprises a first NOT gate, a second OR gate and a register;
a first input end of the third AND gate is respectively connected to the valid signal output end of the front-end module and a second input end of the first AND gate in a logic control circuit in which the third AND gate is located, a second input end of the third AND gate is connected to the feedback signal receiving end of the front-end module, an output end of the third AND gate is connected to an input end of the first NOT gate in the logic control circuit in which the third AND gate is located, an output end of the first NOT gate is connected to a first input end of the second OR gate in the logic control circuit in which the first NOT gate is located, a second input end of the second OR gate is respectively connected to an output end of the second AND gate and one input end of the first OR gate, an output end of the second OR gate is connected to an input end of the register, and an output end of the register is used as the output end of the logic control sub-circuit; and
the register is configured to register an input signal for one clock cycle and then output the input signal.

Optionally, the logic control sub-circuit in the example of the disclosure has the advantages of simple structure and low implementation cost.

Certainly, the logic control sub-circuit may be further of other types apart from the configuration, which will not be limited herein by the example of the disclosure.

As an optional example, the first level is a high level, and the second level is the high level;
the first level processing module is a first OR gate; and
the first logic processing sub-module is a first AND gate, and the second logic processing sub-module comprises a second AND gate and a second NOT gate, a first input end of the second AND gate is used as the first input end of the second logic processing sub-module, an output end of the second AND gate is used as the output end of the second logic processing sub-module, a first end of the second NOT gate is connected to a second input end of the second AND gate, and a second end of the second NOT gate is used as the second input end of the second logic processing sub-module.

Optionally, when the first level and the second level in the example of the disclosure may both be the high levels, the first level processing module may be the first OR gate, the first logic processing sub-module may be the first AND gate, and the second logic processing sub-module may include the second AND gate and the second NOT gate. Thus, the circuit of splitting a handshake signal has the advantages of simple structure and low cost.

Certainly, each module may be further implemented in other ways apart from the configuration, which will not be limited herein by the example of the disclosure.

As an optional example, the first level is a low level, and the second level is a high level; in embodiments of present disclosure, the high level can represent 1 (“1” can be a logic “1”, which indicates 3.3V, or 5V, or an other voltage value preset in the circuit), the low level can represent 0(“0” can be a logic “0”, which indicates 0V or an other voltage value preset in the circuit);
the first level processing module is a first OR gate; and
the first logic processing sub-module comprises a first AND gate and a third NOT gate, and the second logic processing sub-module comprises a second AND gate and a second NOT gate, a first input end of the first AND gate is used as the first input end of the first logic processing sub-module, a second input end of the first AND gate is used as the second input end of the first logic processing sub-module, an output end of the first AND gate is connected to a first end of the third NOT gate, a second end of the third NOT gate is used as the output end of the first logic processing sub-module, a first input end of the second AND gate is used as the first input end of the second logic processing sub-module, an output end of the second AND gate is used as the output end of the second logic processing sub-module, a first end of the second NOT gate is connected to a second input end of the second AND gate, and a second end of the second NOT gate is used as the second input end of the second logic processing sub-module.

Optionally, when the first level in the example of the disclosure may be the low level and the second level may be the high level, the first level processing module may be the first OR gate, the first logic processing sub-module may include the first AND gate and the third NOT gate, and the second logic processing sub-module may include the second AND gate and the second NOT gate. Thus, the circuit of splitting a handshake signal may also complete splitting of the handshake signal, and has the advantages of simple structure and low cost.

Certainly, each module may be further implemented in other ways apart from the configuration, which will not be limited herein by the example of the disclosure.

As an optional example, the circuit of splitting a handshake signal further comprises:
an encapsulation component configured to fix and encapsulate the first OR gate and the each of the logic control circuits.

Optionally, in order to achieve mass production, a corresponding encapsulated circuit having the same number of logic control circuits may be designed for each of the fixed number of back-end modules, thereby improving generation efficiency.

As an optional example, the circuit of splitting a handshake signal further comprises:
a signal enhancement circuit arranged at the feedback signal receiving end of the front-end module and the valid signal receiving end of each of back-end modules comprising the back-end module uniquely corresponding to the each of the logic control circuits, and configured to filter out an interference signal in a signal passing through the signal enhancement circuit.

Optionally, in order to ensure stability and reliability of the handshake signal, a signal enhancement circuit may be further arranged at the feedback signal receiving end of the front-end module and the valid signal receiving end of each of the back-end modules in the example of the disclosure, so as to filter out the interference signals in the signals passing through the signal enhancement circuits, such that the handshake signal is more stable and reliable, thereby reducing an error probability, and improving user experience.

As an optional example, the signal enhancement circuit comprises:
a first filtering module arranged at the feedback signal receiving end of the front-end module, and configured to filter out an interference signal in a feedback signal passing through the first filtering module; and
second filtering modules arranged one-to-one correspondingly at valid signal receiving ends comprising the valid signal receiving end of each of the back-end modules, wherein each of the second filtering modules is configured to filter out an interference signal in a valid signal passing through the each of the second filtering modules.

Optionally, the filtering modules have the advantages of low cost and small size.

Certainly, the signal enhancement circuit may be further of other types apart from the form, which will not be limited herein by the example of the disclosure.

With reference to FIG. 4, a schematic flow diagram of a method of splitting a handshake signal according to the disclosure is shown. The method of splitting a handshake signal comprises:
S401: determining a back-end module of which a feedback signal output end outputs a second level when a valid signal output end of a front-end module outputs a first level;
S402: sending the first level to a valid signal receiving end of the determined back-end module, to cause the determined back-end module to complete a current handshake;
S403: outputting a level opposite to the first level to the valid signal receiving end of the determined back-end module when the front-end module does not complete the current handshake; and
S404: outputting a second level to a feedback signal receiving end of the front-end module only when all back-end modules complete the current handshake.

The disclosure provides the method of splitting a handshake signal. In order to achieve time-divided reception of data by the plurality of back-end modules during signal handshake, in the disclosure, when the valid signal output end of the front-end module outputs the first level and the feedback signal output ends of the back-end modules output the second level, only the back-end modules can be controlled to complete the current handshake. Moreover, before the front-end module completes the current handshake, the level opposite to the first level is output to the valid signal receiving ends of the back-end modules that have completed the handshake, so as to prevent the back-end modules from receiving data anew, and the second level is output to the feedback signal receiving end of the front-end module only when all the back-end modules complete the handshake, such that the front-end module completes the current handshake. Thus, simultaneous/time-divided reception of the data by the plurality of back-end modules is supported, flexibility of data calculation by the back-end modules is improved, and application scenarios are expanded.

For introduction of the method of splitting a handshake signal according to the example of the disclosure, reference is made to the example of the circuit of splitting a handshake signal of the above, which will not be repeated herein by the example of the disclosure.

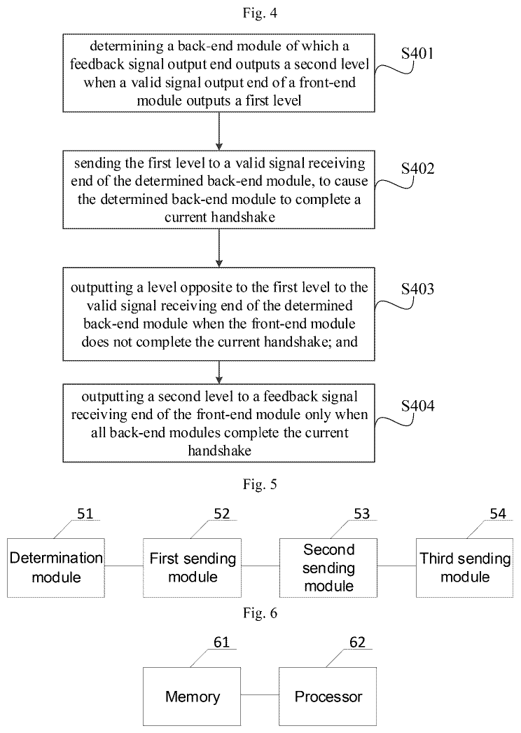

With reference to FIG. 5, a schematic flow diagram of a apparatus of splitting a handshake signal according to the disclosure is shown. The apparatus of splitting a handshake signal comprises:
a determination module 51, configured to determine a back-end module of which a feedback signal output end outputs a second level when a valid signal output end of a front-end module outputs a first level;
a first sending module 52, configured to send the first level to a valid signal receiving end of the determined back-end module, to cause the determined back-end module to complete a current handshake;
a second sending module 53, configured to output a level opposite to the first level to the valid signal receiving end of the determined back-end module when the front-end module does not complete the current handshake; and
a third sending module 54, configured to output a second level to a feedback signal receiving end of the front-end module only when all back-end modules complete the current handshake.

The disclosure provides the apparatus of splitting a handshake signal. In order to achieve time-divided reception of data by the plurality of back-end modules during signal handshake, in the disclosure, when the valid signal output end of the front-end module outputs the first level and the feedback signal output ends of the back-end modules output the second level, only the back-end modules can be controlled to complete the current handshake. Moreover, before the front-end module completes the current handshake, the level opposite to the first level is output to the valid signal receiving ends of the back-end modules that have completed the handshake, so as to prevent the back-end modules from receiving data anew, and the second level is output to the feedback signal receiving end of the front-end module only when all the back-end modules complete the handshake, such that the front-end module completes the current handshake. Thus, simultaneous/time-divided reception of the data by the plurality of back-end modules is supported, flexibility of data calculation by the back-end modules is improved, and application scenarios are expanded.

For introduction of the apparatus of splitting a handshake signal according to the example of the disclosure, reference is made to the example of the circuit of splitting a handshake signal of the above, which will not be repeated herein by the example of the disclosure.

With reference to FIG. 6, a schematic flow diagram of a device of splitting a handshake signal according to the disclosure is shown. The device of splitting a handshake signal comprises:
a memory 61, configured to store a computer program; and
a processor 62, configured to implement steps of the method of splitting a handshake signal in the above example when executing the computer program.

Optionally, the memory comprises a non-volatile readable storage medium, and an internal memory. The non-volatile readable storage medium stores operating system and computer readable instructions, and the internal memory provides an environment for running of the operating system and computer readable instructions in the non-volatile readable storage medium. The processor may implement the following steps when executing the computer program stored in the memory: determining a back-end module of which a feedback signal output end outputs a second level when a valid signal output end of a front-end module outputs a first level; sending the first level to a valid signal receiving end of the determined back-end module, to cause the determined back-end module to complete a current handshake; outputting a level opposite to the first level to the valid signal receiving end of the determined back-end module when the front-end module does not complete the current handshake; and outputting a second level to a feedback signal receiving end of the front-end module only when all back-end modules complete the current handshake.

The disclosure provides the device of splitting a handshake signal. In order to achieve time-divided reception of data by the plurality of back-end modules during signal handshake, in the disclosure, when the valid signal output end of the front-end module outputs the first level and the feedback signal output ends of the back-end modules output the second level, only the back-end modules can be controlled to complete the current handshake. Moreover, before the front-end module completes the current handshake, the level opposite to the first level is output to the valid signal receiving ends of the back-end modules that have completed the handshake, so as to prevent the back-end modules from receiving data anew, and the second level is output to the feedback signal receiving end of the front-end module only when all the back-end modules complete the handshake, such that the front-end module completes the current handshake. Thus, simultaneous/time-divided reception of the data by the plurality of back-end modules is supported, flexibility of data calculation by the back-end modules is improved, and application scenarios are expanded.

For introduction of the device of splitting a handshake signal according to the example of the disclosure, reference is made to the example of the circuit of splitting a handshake signal of the above, which will not be repeated herein by the example of the disclosure.

The disclosure provides a non-volatile readable storage medium. The non-volatile readable storage medium stores a computer program. The computer program implements steps of the method of splitting a handshake signal in the above example when executed by a processor.

Optionally, the non-volatile readable storage medium may include various media capable of storing program codes, such as a USB flash drive, a mobile hard disk, a read-only memory (ROM), a random access memory (RAM), a magnetic disk, or an optical disk. The storage medium stores the computer program, and the computer program implements the following steps when executed by the processor: determining a back-end module of which a feedback signal output end outputs a second level when a valid signal output end of a front-end module outputs a first level; sending the first level to a valid signal receiving end of the determined back-end module, to cause the determined back-end module to complete a current handshake; outputting a level opposite to the first level to the valid signal receiving end of the determined back-end module when the front-end module does not complete the current handshake; and outputting a second level to a feedback signal receiving end of the front-end module only when all back-end modules complete the current handshake.

The disclosure provides the non-volatile readable storage medium. In order to achieve time-divided reception of data by the plurality of back-end modules during signal handshake, in the disclosure, when the valid signal output end of the front-end module outputs the first level and the feedback signal output ends of the back-end modules output the second level, only the back-end modules can be controlled to complete the current handshake. Moreover, before the front-end module completes the current handshake, the level opposite to the first level is output to the valid signal receiving ends of the back-end modules that have completed the handshake, so as to prevent the back-end modules from receiving data anew, and the second level is output to the feedback signal receiving end of the front-end module only when all the back-end modules complete the handshake, such that the front-end module completes the current handshake. Thus, simultaneous/timed reception of the data by the plurality of back-end modules is supported, flexibility of data calculation by the back-end modules is improved, and application scenarios are expanded.

For introduction of the non-volatile readable storage medium according to the example of the disclosure, reference is made to the example of the circuit of splitting a handshake signal of the above, which will not be repeated herein by the example of the disclosure.

The disclosure provides a digital chip. The digital chip comprises a server body, further comprises the circuit of splitting a handshake signal in the above example that is connected to the server body, and further comprises a front-end module and a plurality of back-end modules.

The circuit of splitting a handshake signal is connected to the front-end module and each of the back-end modules.

For introduction of the digital chip according to the example of the disclosure, reference is made to the example of the circuit of splitting a handshake signal of the above, which will not be repeated herein by the example of the disclosure.

The disclosure provides a server. The server comprises the digital chip in the above example.

For introduction of the server according to the example of the disclosure, reference is made to the example of the circuit of splitting a handshake signal of the above, which will not be repeated herein by the example of the disclosure.

Each example in the description is described in a progressive manner, each example focuses on the differences from other examples, and the same and similar parts between the examples can refer to each other. Since an apparatus disclosed in the example corresponds to the method disclosed in the example, the description is relatively simple, and for relevant contents, reference can be made to partial description of the method. It should be further noted that relational terms in the description, such as first and second are merely used to distinguish one entity or operation from another entity or operation without necessarily requiring or implying any actual such relation or order between such entities or operations. Moreover, the terms “comprise” and “include” or any other variations thereof are intended to cover non-exclusive inclusions, such that a process, a method, an article, or a device including a series of elements not only comprises those elements, but also comprises other elements that are not explicitly listed, or further comprises inherent elements of the process, the method, the article, or the device. Without more restrictions, the elements defined by the sentences “comprise a . . . ” and “include a . . . ” do not exclude the existence of other identical elements in the process, the method, the article, or the device including the elements.

The above description of the examples disclosed enables those skilled in the art to achieve or use the disclosure. Various modifications to these examples are readily apparent to those skilled in the art, and the general principles defined herein can be implemented in other examples without departing from the spirit or scope of the disclosure. Therefore, the disclosure is not limited to the examples shown herein but falls within the widest scope consistent with the principles and novel features disclosed herein.

1. A circuit of splitting a handshake signal, comprising:
a first level processing module, wherein an output end of the first level processing module is connected to a feedback signal receiving end of a front-end module, and each of input ends of the first level processing module is connected one-to-one with a first output end of each of logic control circuits, the first level processing module is configured to output a second level only when each of the input ends is at the second level;
a second level processing module, wherein a first input end of the second level processing module is connected to the output end of the first level processing module, and a second input end of the second level processing module is connected to a valid signal output end of the front-end module; and
the logic control circuits, wherein a first input end of each of the logic control circuits is connected to an output end of the second level processing module, a second input end of the each of the logic control circuits is connected to a feedback signal output end of a back-end module uniquely corresponding to the each of the logic control circuits, a second output end of the each of the logic control circuits is connected to a valid signal receiving end of the back-end module uniquely corresponding to the each of the logic control circuits, and a third input end of the each of the logic control circuits is connected to the valid signal output end of the front-end module, the each of the logic control circuits is configured to, in cooperation with an output signal of the second level processing module, send, when the valid signal output end outputs a first level and the feedback signal output end connected to the each of the logic control circuits outputs the second level, the first level to the valid signal receiving end connected to the each of the logic control circuits, to cause the each of the logic control circuits and the back-end module corresponding to the each of the logic control circuits to complete a current handshake; and output, after the back-end module corresponding to the each of the logic control circuits completes the current handshake and before the front-end module completes the current handshake, a level opposite to the first level to the valid signal receiving end connected to the each of the logic control circuits and the second level to the first level processing module.

2. The circuit of splitting a handshake signal according to claim 1, wherein the front-end module is configured to prepare a piece of data during each handshake, the back-end module is configured to acquire the data corresponding to the current handshake while the current handshake is successful, and the front-end module is further configured to prepare a next piece of data after the back-end module acquires the data corresponding to the current handshake.

3. The circuit of splitting a handshake signal according to claim 1, wherein the each of the logic control circuits comprises a logic control sub-circuit, a first logic processing sub-module and a second logic processing sub-module, wherein
a first input end of the logic control sub-circuit is connected to the output end of the second level processing module, an output end of the logic control sub-circuit is connected to a first input end of the first logic processing sub-module and a first input end of the second logic processing sub-module respectively, a second input end of the first logic processing sub-module is connected to the valid signal output end of the front-end module, an output end of the first logic processing sub-module is used as the second output end of the each of the logic control circuits, a second input end of the second logic processing sub-module is used as the second input end of the each of the logic control circuits, and an output end of the second logic processing sub-module is used as a first output end of the each of the logic control circuits and is connected to a second input end of the logic control sub-circuit;
the logic control sub-circuit is configured to, in cooperation with the output signal of the second level processing module, output the first level when the valid signal output end outputs the first level and the feedback signal output end corresponding to the each of the logic control circuits outputs the second level, to cause the each of the logic control circuits and the back-end module corresponding to the each of the logic control circuits to complete the current handshake; and output the second level after the back-end module corresponding to the each of the logic control circuits completes the current handshake and before the front-end module completes the current handshake;
the first logic processing sub-module is configured to output the first level only when the first input end and the second input end of the first logic processing sub-module are both at the first level;
the second logic processing sub-module is configured to output the second level only when the first input end and the second input end of the second logic processing sub-module are both at the second level.

4. The circuit of splitting a handshake signal according to claim 3, wherein the first level is a high level, and the second level is a low level, the high level represents 1, and the low level represents 0;
the first level processing module is a first OR gate; and
the first logic processing sub-module is a first AND gate, the second logic processing sub-module is a second AND gate, and the second level processing module is a third AND gate.

5. The circuit of splitting a handshake signal according to claim 4, wherein
the first level processing module is configured to execute an OR operation on input signals; and
the first logic processing sub-module, the second logic processing sub-module, and the second level processing module are configured to execute an AND operation on input signals respectively.

6. The circuit of splitting a handshake signal according to claim 4, wherein the logic control sub-circuit comprises a first NOT gate, a second OR gate and a register;
a first input end of the third AND gate is respectively connected to the valid signal output end of the front-end module and a second input end of the first AND gate in a logic control circuit in which the third AND gate is located, a second input end of the third AND gate is connected to the feedback signal receiving end of the front-end module, an output end of the third AND gate is connected to an input end of the first NOT gate in the logic control circuit in which the third AND gate is located, an output end of the first NOT gate is connected to a first input end of the second OR gate in the logic control circuit in which the first NOT gate is located, a second input end of the second OR gate is respectively connected to an output end of the second AND gate and one input end of the first OR gate, an output end of the second OR gate is connected to an input end of the register, and an output end of the register is used as the output end of the logic control sub-circuit; and
the register is configured to register an input signal for one clock cycle and then output the input signal.

7. The circuit of splitting a handshake signal according to claim 3, wherein the first level is a high level, and the second level is the high level, the high level represents 1, and the low level represents 0;
the first level processing module is a first OR gate; and
the first logic processing sub-module is a first AND gate, and the second logic processing sub-module comprises a second AND gate and a second NOT gate, a first input end of the second AND gate is used as the first input end of the second logic processing sub-module, an output end of the second AND gate is used as the output end of the second logic processing sub-module, a first end of the second NOT gate is connected to a second input end of the second AND gate, and a second end of the second NOT gate is used as the second input end of the second logic processing sub-module.

8. The circuit of splitting a handshake signal according to claim 7, wherein
the first level processing module is configured to execute an OR operation on input signals; and
the first logic processing sub-module is configured to execute an AND operation on input signals, and the second logic processing sub-module is configured to execute a NOT operation on a signal input at the second input end of the second logic processing sub-module, then execute an AND operation on an operation result of the NOT operation and a signal input at the first input end of the second logic processing sub-module, and output an operation result of the AND operation.

9. The circuit of splitting a handshake signal according to claim 3, wherein the first level is a low level, and the second level is a high level, the high level represents 1, and the low level represents 0;
the first level processing module is a first OR gate; and
the first logic processing sub-module comprises a first AND gate and a third NOT gate, and the second logic processing sub-module comprises a second AND gate and a second NOT gate, a first input end of the first AND gate is used as the first input end of the first logic processing sub-module, a second input end of the first AND gate is used as the second input end of the first logic processing sub-module, an output end of the first AND gate is connected to a first end of the third NOT gate, a second end of the third NOT gate is used as the output end of the first logic processing sub-module, a first input end of the second AND gate is used as the first input end of the second logic processing sub-module, an output end of the second AND gate is used as the output end of the second logic processing sub-module, a first end of the second NOT gate is connected to a second input end of the second AND gate, and a second end of the second NOT gate is used as the second input end of the second logic processing sub-module.

10. The circuit of splitting a handshake signal according to claim 9, wherein
the first level processing module is configured to execute an OR operation on input signals;
the first logic processing sub-module is configured to execute an AND operation on input signals, then execute a NOT operation on an operation result of the AND operation, and output an operation result of the NOT operation; and
the second logic processing sub-module is configured to execute a NOT operation on a signal input at the second input end of the second logic processing sub-module, then execute an AND operation on an operation result of the NOT operation and a signal input at the first input end of the second logic processing sub-module, and output an operation result of the AND operation.

11. The circuit of splitting a handshake signal according to claim 4, further comprising:
an encapsulation component configured to fix and encapsulate the first OR gate and the each of the logic control circuits.

12. The circuit of splitting a handshake signal according to claim 1, further comprising:
a signal enhancement circuit arranged at the feedback signal receiving end of the front-end module and the valid signal receiving end of each of back-end modules comprising the back-end module uniquely corresponding to the each of the logic control circuits, and configured to filter out an interference signal in a signal passing through the signal enhancement circuit.

13. The circuit of splitting a handshake signal according to claim 12, wherein the signal enhancement circuit comprises:
a first filtering module arranged at the feedback signal receiving end of the front-end module, and configured to filter out an interference signal in a feedback signal passing through the first filtering module; and
second filtering modules arranged one-to-one correspondingly at valid signal receiving ends comprising the valid signal receiving end of each of the back-end modules, wherein each of the second filtering modules is configured to filter out an interference signal in a valid signal passing through the each of the second filtering modules.

14. The circuit of splitting a handshake signal according to claim 1, wherein the handshake signal comprises a handshake signal of a Valid/Stop protocol.

15. A method of splitting a handshake signal, comprising:
determining a back-end module of which a feedback signal output end outputs a second level when a valid signal output end of a front-end module outputs a first level;
sending the first level to a valid signal receiving end of the determined back-end module, to cause the determined back-end module to complete a current handshake;
outputting a level opposite to the first level to the valid signal receiving end of the determined back-end module when the front-end module does not complete the current handshake; and
outputting a second level to a feedback signal receiving end of the front-end module only when all back-end modules complete the current handshake.

16. (canceled)

17. A device of splitting a handshake signal, comprising:
a memory, configured to store a computer program; and
a processor, configured to implement steps of the method of splitting a handshake signal according to claim 15 when executing the computer program.

18. A non-volatile readable storage medium, storing a computer program, wherein the computer program implements steps of the method of splitting a handshake signal according to claim 15 when executed by a processor.

19. A digital chip, comprising: the circuit of splitting a handshake signal according to claim 1, a front-end module and a plurality of back-end modules, wherein
the circuit of splitting a handshake signal is connected to the front-end module and each of the back-end modules.

20. A server, comprising: a server body, and the digital chip according to claim 19 that is connected to the server body.

21. The circuit of splitting a handshake signal according to claim 2, further comprising:
a signal enhancement circuit arranged at the feedback signal receiving end of the front-end module and the valid signal receiving end of each of back-end modules comprising the back-end module uniquely corresponding to the each of the logic control circuits, and configured to filter out an interference signal in a signal passing through the signal enhancement circuit.
